(19) United States
(12) Patent Application Publication
(10) Pub. No.: US 2014/0331572 A1
(43) Pub. Date: Nov. 13, 2014

(54) Modular system with solar roof

(71) Applicant: Edward James Singelyn, JR., Lake Elsinore, CA (US)

(72) Inventor: Edward James Singelyn, JR., Lake Elsinore, CA (US)

(21) Appl. No.: 13/999,700

(22) Filed: Mar. 18, 2014

Related U.S. Application Data
(60) Provisional application No. 61/852,328, filed on Mar. 15, 2013.

(51) Int. Cl. H01L 31/048; E04H 1/00; F24J 2/52

(52) U.S. Cl. CPC H01L 31/0482; H01L 31/0485; F24J 2/5245; E04H 1/005
USPC 52/173.3

(57) ABSTRACT

A series of individual modular panels are combined to create a completed structure. Panels for floor, wall and roof are joined at common bearing points. The roof frame is a combination of pyramid and hip shaped units connected to create the structural framework for standard and multi-pitched pyramid and hip-type roofs. The structural framework acts as a single unit and creates both the exterior and interior shape in one assembly. The lower horizontal carriage of the roofs structural framework allows for easy installation of ceiling panels. The upper exterior diagonal and horizontal framework allows for easily installed weather tight roof panels. PV solar panels can be integrated into the roof panels, eliminating the need for additional racking. Lightweight tents as well as heavy commercial applications can benefit from this roof system. Electric supply lines are accommodated for with hollow channels integrated into the structural assembly.

### BACKGROUND OF THE INVENTION

1. Field of the Invention

The present invention relates generally to building construction and more specifically to the use of factory made panels and a modular roof system to assemble a wide variety of structures including low cost, energy efficient housing.

2. Description of Related Art Including Information Disclosed Under 37 CFR 1.97 and 1.98

General contractors have seen many changes in the building industry over the last few decades. The addition of new methods and new building materials has improved the end product. These include OSB sheathing, engineered floor joists, USG lightweight drywall, 2× roof trusses, foam core stress skin panels, (SIP's), fiberglass strand moisture barrier, dual glazed vinyl windows, silicone caulking, ABS plumbing parts and most recently PV electricity producing solar panels. However even with the improvements in materials field construction is still very expensive, time consuming and can be an overall logistics nightmare.

Panelized systems have been presented in the past, some say beginning with Frank Loyd Wrights initialization of the Usonian era. To create a low cost dwelling his idea was to decrease field construction time with the factory made parts. Mr. Wright introduced several innovative concepts including the use and sandwich panels, similar to todays (SIP) modules. He was not a big fan of air conditioning so he used solar orientation to accomplish temperature control with varying degrees of success. He also selected flat roofs as a further solution towards savings in materials and labor costs. The concept to create low cost housing was valid then and even more relevant today. Panelized systems of the past often lacked versatility and have met with little acceptance for a variety of reasons. Customized parts are often too expensive to manufacture and distribute. Electrical wiring and energy efficiency present imposing factors. Moreover an acceptable roof system has not been presented that would be attractive enough for builders to replace tried and true methods, especially in the housing and commercial industry. Finally there has not been a complete panelized system presented from foundation thru roof that will meet code requirements and industry standards for energy efficiency and still be cost effective. Today modern materials and the system presented offer the solution.

From a cost perspective roofs are the most expensive part of framing a home. They require the most skilled tradesmen in the industry and they are the most dangerous part of a structure to build. Hip roofs are especially expensive and difficult to build as they are not readily assembled with today's modern wooden truss. However because of their attractive profile they are used extensively in both residential and commercial projects.

Today the least expensive roof to build would be a straight gable, no hips, no valleys. They are generally built with one size open web wooden trusses. Short spans of 32′ would be made out of 2×4 lumber using gang nail type steel plates at the joints. Longer spans are possible with increased lumber and plate sizes. Carpenters often opt to build short span roofs with a single ridge beam, angle cut rafters and cross ties to hold opposing walls in place. As spans get wider trusses become the more economical choice. Transportation and roof top loading require special equipment as well and add extra costs. Once the framing members are in place and properly braced roof top work begins. Most common and least expensive is the application of OSB sheathing or plywood, followed by the installation of fiberglass roof shingles or lengths of sheet metal. In the past some old world weather proofing methods included slate shingles or wooden shingles, metal shingles, and even thatch. All of these know practices require dangerous roof top application and are expensive and time consuming. Today roofing costs for workman's compensation insurance is now over $120 per every $100 in wages paid to an employee. Only demolition and explosives carry a higher rate. Factory work by comparison as herein proposed carries a rate of less than $10 per every $100 paid to an employee. (Verify)

Hip roofs are particularly desirable in custom homes as they do not have a stark ending point as in a typical gable end truss roof design. Hip roofs can also be advantageous when planning to include a PV electrical system as by design there are four sides to choose from to get proper orientation to the sun vs. two for a gable roof.

A major road block toward full implementation of solar powered homes is the overall expense. In general 4-6 dollars per panel watt is the current price to install a PV system on an existing home. Amortized over a number of years this is still an attractive investment for many homeowners. Paying for the generation system many times over when allowing for projected increases in grid provided electricity.

The system as presented goes beyond this line of logic and includes covering the cost of the roof as well. Here PV collection could be installed for as little as $2 per panel watt. In the U.S a range of 2.5 k-5 k panel watts is a fairly typical installed size. In general the overall cost would be in the twelve to twenty-five thousand dollar range. Given that the system presented is less than half of a typical installed price. The savings would easily cover the cost of the roof and qualify for a current 30% government incentive. Amortized over a number of years the savings on electricity would also go a long ways toward paying for the solar home as well.

New regulations, the cost of electricity and environmental concerns are quickly changing the public view of privately owned PV systems in the U.S. Photo voltaic solar is now a standard option for consumers when buying a new home. Someday it may even become mandatory as we have seen with the implementation of Title 24 energy requirements in new home construction.

A number of patents and or publications have been made to address the issues as stated. Exemplary examples of patents and or publication that try to address this/these problem(s) are identified and discussed below.

U.S. Pat. No. 2,682,235 entitled BUILDING CONSTRUCTION by BUCKMINSTER FULLER famous for his geodesic dome in the housing industry among many other great innovations. By using similar size modules he increased a home's volume with a minimal use of material.

U.S. Pat. No. 3,014,558 entitled SHELTER STRUCTURE

This patent lacks the structural and design elements of the newly presented invention.

U.S. Pat. No. 3,738,083 entitled PREFABRICATED HOUSE

This patent lacks the design and structural elements of the newly presented invention.

U.S. Pat. No. 4,516,363 entitled SUPERINSULATION ROOF RAFTERS AND BUILDING SYSTEM

This patent lacks the design and structural elements of the newly presented invention.

U.S. Pat. No. 6,311,446 B1 entitled PREFABRICATED HIP ROOF

This patent offers a precut or kit type product engineered to decrease the time needed for field assembly as well as a lessening of the need for skilled labor. However the framing of the hip roof is not unilaterally connected creating a single frame as in the present invention. The roof covering is described as pre-cut pieces suggesting shapes that would not be applicable to the present invention nor is the method of fastening.

U.S. Pat. No. 7,012,188 entitled FRAMING SYSTEM FOR SOLAR PANELS

This patent lacks the design and structural elements of the newly presented invention.

U.S. Pat. No. 8,065,840 entitled MODULAR BUILDING CONSTRUCTION

This patent lacks the design and structural elements of the newly presented invention.

U.S. Pat. No. 8,286,392 entitled INHABITABLE SPACE FRAMES

This patent lacks the design and structural elements of the newly presented invention.

U.S. Pat. No. 8,476,523 entitled SOLAR PANEL READY TILES

This patent lacks the design and structural elements of the newly presented invention.

U.S. Pat. No. 8,512,866 entitled FLEXIBLE SOLAR PANEL WITH MULTILAYERED FILM

This patent lacks the design and structural elements of the newly presented invention.

This patent lacks the design and structural elements of the newly presented invention.

U.S. Patent Number 2013/0280448 A1 entitled SOLAR PANEL READY TILES

This patent lacks the design and structural elements of the newly presented invention.

U.S. Pat. No. 8,539,734 entitled ROOF TRUSS COMPATIBLE FOR SOLAR PANELS

This patent lacks the design and structural elements of the newly presented invention.

What is needed is. The need for low cost, low impact housing is tackled from the approach that a prefabricated energy efficient design is required.

### BRIEF SUMMARY OF THE INVENTION

A primary concept of the invention is to build a complete habitable structure predominantly with factory built components in order to minimize over all costs and assembly time in the field. Structures are designed to meet building standards for strength and energy efficiency. The roofs truss type frame of interconnected members offers a large degree of flexibility in so far as it is expandable in upward and outward directions while providing support for both the interior and exterior skin applications. Included in the roof panel installation is a method for including photo voltaic solar electric conductors directly within, without the need of additional mounting hardware. The roof frame is inherently sound without the need of an additional shear membrane such as OSB or plywood. Further, an acceptable method is described for installing the prefabricated components of the structure to allow for the possibility of dis-assembly if desired.

The roofs structural frame (carriage) is made with a combination of four sided pyramid and hip shaped structural modules. When combined with additional modules, having one or more horizontal members in common, an integrated structural system is created that gives both size and strength to roof structures. The number and size of the combined modules will determine the overall size of the roof structure. The pitch or angle of the modules and placement thereof will determine the appearance of the roof shape. Ultimately the structural framework is provided for both the exterior and interior in a single integrated roof along with a simplified method of installing skin applications. A clearer understanding of the invention is provided in more detail below.

It is an object of the invention to teach a low cost method of building a prefabricated house with a solar roof.

It is another object of the invention to teach how to build a solar roof independent of a prefabricated house.

It is an object of the invention to teach how to build a roof independent of a solar roof.

It is an object of the invention to minimize field construction time by the use of prefabricated floor and wall panels and a modular roof system.

It is an object of the floor, wall and roof system to meet acceptable building standards for strength and energy efficiency.

It is an object of the floor, wall and roof system to provide a method for installing accessible electrical pathways including a method for integration of photo voltaic electricity.

It is an object of the invention that the floor, wall and roof system will have common bearing points to transfer loads to the footings, eliminating the need for headers above windows and doors.

It is an object of the roof system that independent of a floor and wall panel system roof loads can be transferred to the footings by the use of spaced apart posts at selected roof member junctions

It is another object of the roof system that prefabricated roof panels can be made from a variety of material and installed in a weather tight overlapping manner.

It is another object of the roof system to have the ability to be installed from the inside of the building by attaching to horizontal and diagonal members. A safety element.

It is another object of the invention that the entire roof system could be built on the ground and lifted into place with a crane or other hoisting method.

It is an object of the roof system to provide a roof frame made from structural modules combined together to form a larger structural roof frame.

It is another object of the exterior roof frame to accept prefabricated quadrilateral and triangular shaped roof panels directly supported by the members of the space frame to seal out elements of weather.

Other key factors include the ability of the structure to provide for its own electrical needs with the use of solar cells where by all electrical connection are made from within the interior of the roof

It is another object of the invention to create a buffer zone by use of insulated roof panels and insulated ceiling panels.

It is another object of the invention for wall panels to have preinstalled electrical outlets serviced by an electrical feed line encompassed in the hollow top plate.

It is another object of the invention to control the ambient temperature in the buffer zone with the use a solar activated fan, thermostatically controlled.

It is another object of the interior of the roof frame to accept insulated ceiling panels as well as provide structural integrity as tension members.

It is another object of the roof frame to act as a solar rack for direct mounting of photo voltaic panels. This decreases the overall cost and virtually eliminates any chance of theft of solar panel as they are locked into the roof system. Also qualifying the roof for government incentives.

It is another object of the invention that the benefit of installing a solar electric system in the manner presented will offset the overall cost of the entire structure when compared to a standard installation with other known methods.

It is another object of invention to show the flexability and versatility of the floor, wall and roof design.

Various objects, features, aspects, and advantages of the present invention will become more apparent from the following detailed description of preferred embodiments of the invention, along with the accompanying drawings in which like numerals represent like components.

### BRIEF DESCRIPTION OF THE SEVERAL VIEWS OF THE DRAWING(S)

FIG. 1 shows a perspective view of a wall and floor assembly and a wire frame drawing of the roof design in order to show load transfer to the pier block footing below.

FIG. 2 shows a blow up of the wall and floor assembly from FIG. 1

FIG. 3 shows the steel wrap for floor panels and connection to H beam

FIG. 4 shows an offset joint for floor panels.

FIG. 5 shows a bolt connection for offset joints of H beams and H posts for wall sections where applicable

FIG. 6 shows a top view of typical H post wall connections and end detail. The design is to be light weight

FIG. 7 shows individual wall panel frames

FIG. 8 shows various sizes of wall frames

FIG. 9 shows a rectangular building and hip roof

FIG. 10 shows a top view for a rectangular building with floor beam and wall joint locations

FIG. 11 shows a top view for a rectangular building with floor beam locations, wall joint locations with extended top plates layout to support the corners of the overhang eve and the first course of the roof system with bearing locations.

FIG. 12 shows a double stack rectangular hip roof and panel locations created by six base modules and two altered angled upper modules

FIG. 13 shows a triple stack pyramid roof created by nine base modules and four altered angled upper modules with another altered angle module on top.

FIG. 14 shows a top piece for a central ceiling joint connection. Connector includes ring attachment with bolt locations for angled couplers or struts. Coupler is used to attach ceiling T bars to above assembly and acts to secure tension members

FIG. 15 shows an alternate method for connecting diagonal members to the bottom carriage with an adjustable hinge.

FIG. 16 shows connector for drop ceiling carriage tension members.

FIG. 17 shows an upward assembly method with couplers location and vertical member assembly.

FIG. 18 shows tubular connection joints in unbent and bent conditions.

FIG. 19 shows an 8 strut union coupler with equal angled members to create an equal sided panel roof and an 8 strut union coupler with non-equal angled members to create an non-equal sided roof.

FIG. 20 shows an equal sided pyramid shaped roof and location of triangular roof panels.

FIG. 21 shows an isometric view of the structural framework of a pyramid roof.

FIG. 22 shows how joints for triangle stress skin panels would overlap and how they would lock to diagonal and corner members of roof frame

FIG. 23 shows how a corner detail would look also locking out moisture.

FIG. 24 shows an upper perspective view of a double angle rectangle roof.

FIG. 25 shows a lower perspective view of the same roofs lower carriage structure.

FIG. 26 shows a top view of a 4 stack rectangular roof and location of rectangular modules to create a right angle hip on 2 sides for the installation of square solar panels.

FIG. 27 shows the panel locations of FIG. 26 using quadrilateral panels.

FIG. 28 shows an elongated hip roof or racking system capable of many more solar panels.

FIG. 29 shows individual triangle panels spaced apart to make a pyramid roof.

FIG. 30 shows triangle panels joints as assembled across.

FIG. 31 shows triangle panels assembled across and downward to form a weather tight pyramid roof.

FIG. 32 shows triangle locations for a hip roof.

FIG. 33 shows interlocking solar panels. Horizontal line indicates a split panel assembly.

FIG. 34 shows perspective view of alternate shape and post points.

FIG. 35 shows top view of FIG. 34 with panels in place and post locations.

### DETAILED DESCRIPTION OF THE INVENTION

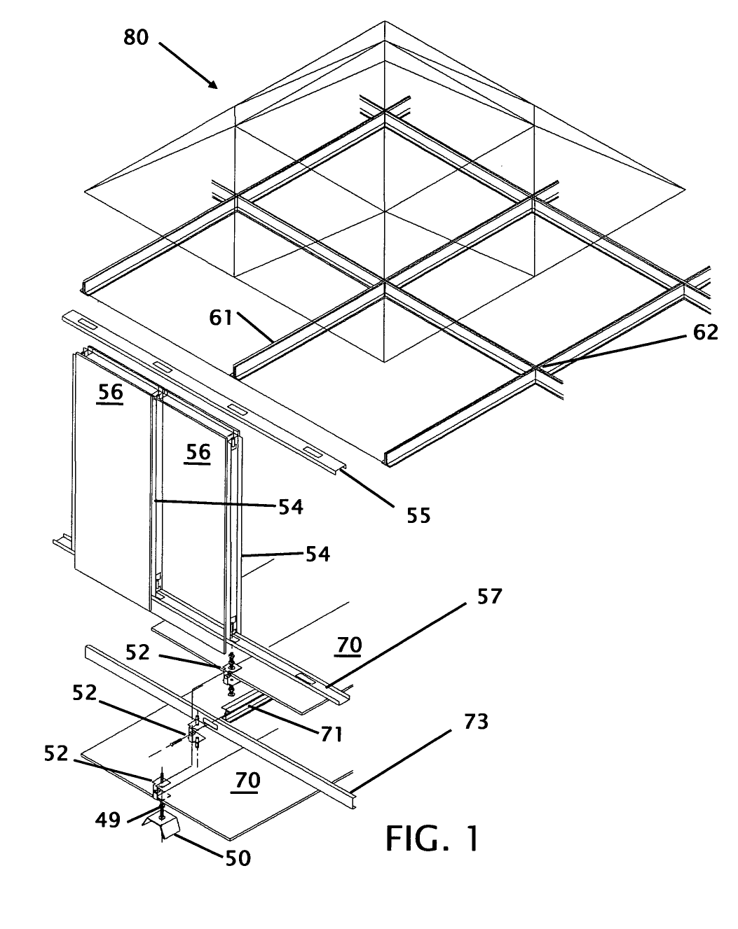

FIG. 1 shows an illustration of the general concept of the required elements to build a complete structure from the roof down to the connection support pier at the ground. For descriptive purposes dimensions used are known standard modular sizes for cost and availability. Therefore In one embodiment the floor and wall panels will share common bearing points around the exterior perimeter at 4′ centers. The roof will share common bearing points around the perimeter at 8′ centers.

Piers 50 are located at the common bearing points. Adjustable height bolt 49 and steel connection coupler 52 are designed to connect H beam 71 of the floor assembly to H post 54 of the wall assembly. Floor panel assemblies 70 have a continuous steel stud rim joist 73 designed to keep floor assemblies aligned. Wall panels 56 have a continuous metal stud bottom plate 57 and a continuous metal stud top plate 55 designed to keep wall panels 56 aligned. Butt joints of continuous metal members should be offset panel breaks. T section (double L's) of roof assembly 61 is attached to top plate 55 thru bolt or equal.

Steel studs come in a variety of widths and metal gauges. H beams 71 and H posts 54 are a combination of 2 studs fastened back to back. Floor beams become the load transferring members for the floor panel assemblies. Wall posts become the load bearing members of the roof assemblies. Steel studs are readily available and are often used in place of lumber due to their dependable nature. Here they are rearranged and assembled from their traditional framing method into a direct load bearing transfer method similar to post and beam construction.

T bar lengths 61 (double L's) are shown cris-crossing 62 from side to side at 8′ on center to form the base of the roof assembly. Upper portion of the roof assembly 80 shown here as a wire frame schematic also indicating 8′ on center bearing points. The exterior perimeter will use a single L bar similar in height to 61 or designed to accommodate the height of a stress skin panel. The center portions of the frames are then filled in with stress skin panels keeping within the spirit of the invention. Light weight drywall from USG is an excellent choice for wall and ceiling panels. Stress skin panels ceiling panels having a poly insulation core generally require a fire protection layer of ½″ drywall. A 4′ module size is common for exterior skin plywood as well. By keeping panel members as light as possible field assembly can be handled by a two man crew eliminating the need for special equipment.

Tension members 61 are designed to couple at intersections and receive a two piece X section coupler for the attachment of 4 swaged pipe tubes. The coupler can include a method for attaching a vertical strut as well depending on span and load requirements. Tubular struts are available in a variety of widths and metal gauges. The choice will be dependent on the overall unsupported span of the roof frame and type of roof material and zonal loading requirements.

Tubular members run diagonally to upper intersections where they meet with truss and exterior shape of the roof. The exterior shape of the roof is then filled in with triangular shaped stress skin panels that lock or clamp into place. The panels are designed to provide a weather tight exterior skin using painted aluminum or equal and can be ribbed to increase the strength. The foam poly core center provides needed insulation with the overall effect of creating a foyer in the void area of the ceiling to help control temperatures inside the home.

North side eve vents and an upper ridge vent or Dutch vent will reduce the ambient attic temperature allowing the stress skins of the lower T bar frame to function more efficiently. A solar powered temperature controlled fan in the attic foyer would control the ambient temperature. Most climate zones will not require air conditioning to cool the home. Unlike a standard gable roof heat is not trapped with this design concept.

The roof frame will accommodate triangle shaped stress skin panels with an added capability of being installed from the interior of the building. From a cost perspective the material used in the described method is within reason when compared to other methods. However the savings in labor is substantial. In addition this method provides a simple solution for the installation of PV electricity. Thin film solar cells are available in rolls and can be applied in advance to the stress skin roof panels. They are designed to adhere to a number of substrates. The conversion rate for thin film has surpassed 20% vs. a standard poly crystal glass panel at just over 14%.

It is well known that heat buildup cuts efficiency as well. In the core of the described solar roof panel accommodation for heat sink aluminum honey combs could provide a savings benefit.

Roof top work is expensive and dangerous. This system eliminates many associated costs and risks over standard methods. Roof top work carries the highest workman's compensation rate in the industry only surpassed by demolition and explosives. For every $100 in man wages add $120 for insurance. In addition factory work vs. field work carries a rates as low as $8 per every $100 in man labor. Not to mention most of the work is jigged and labor becomes more efficient. Today more than ever it makes sense to prefabricate.

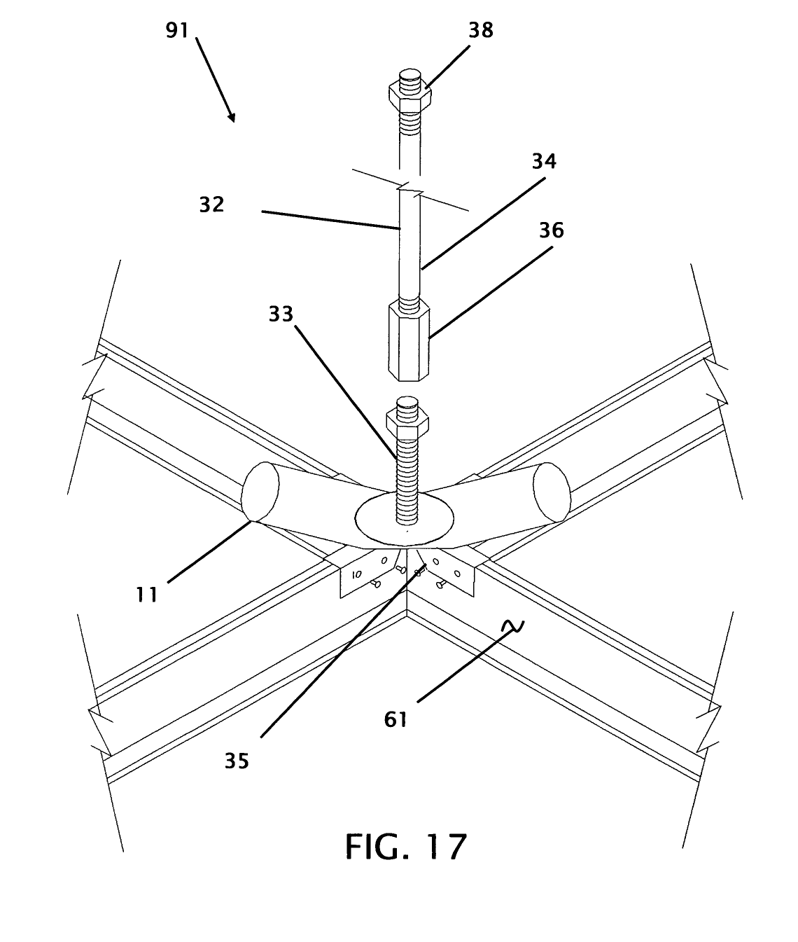

The embodiment described has several labor and energy saving advantages in relation to both residential and commercial structures. In an alternate described embodiment lighter weight tent type structures also benefit from the use of this modular roof system. The tension bar ceiling would be eliminated and replaced with a tube receiving connection as shown FIGS. 18 and 19. The ability to build lighter weight roofs using smaller tube sizes has several advantages. Roof shapes can be unique and interesting and fabric can be attached at multiple locations rather than with much larger one or two piece tent material.

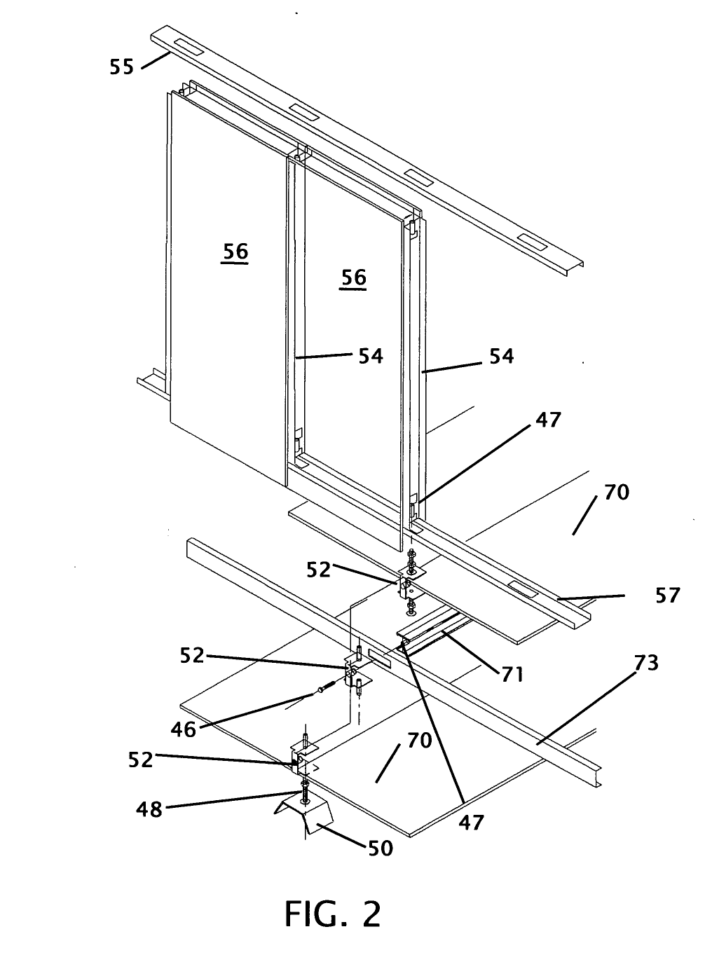

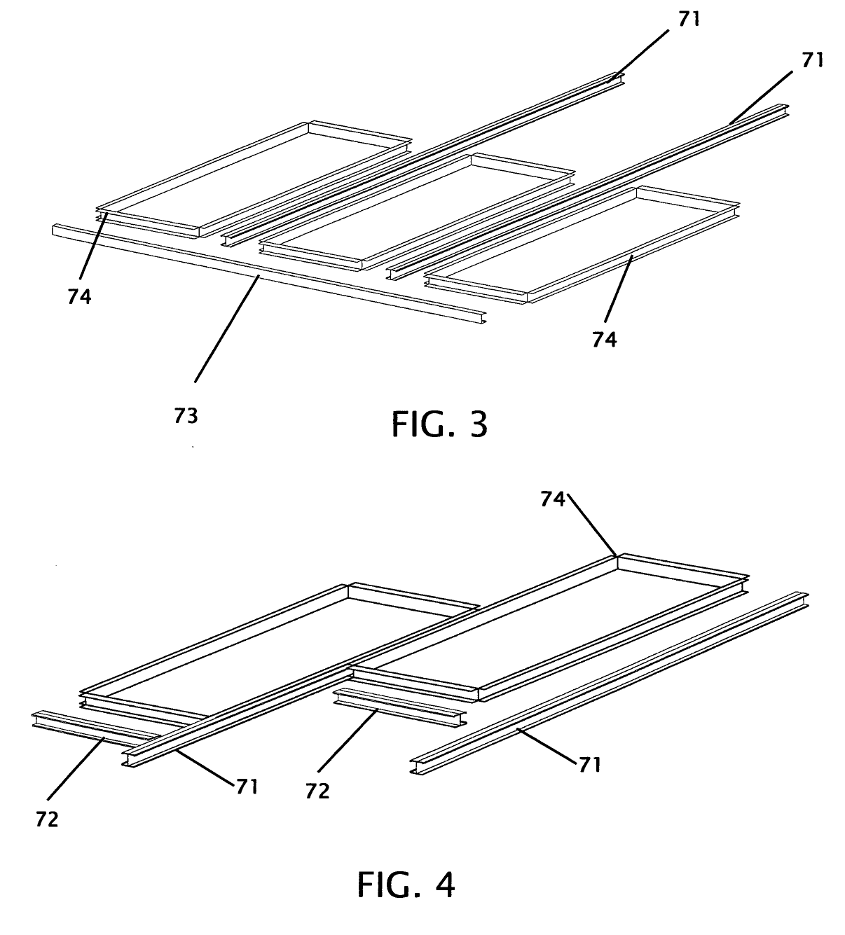

FIG. 2 shows the perspective view of a wall and floor assembly as in FIG. 1 without the ceiling or roof assembly for a clearer picture. Coupler 52 with top and bottom bolt is attached to receiver 47 of H post 54 and also attached to floor beam 71 with thru bolt 46. Wall panel 56 is shown with a transparent skin for better understanding in relation to FIGS. 3 and 4

FIG. 3 shows the steel wrap 74 for floor panels and connection method to H beam 71. Steal wrap is a receiver formed from C channel also available in multiple gauges sometime called track. It is designed to give structural integrity to the corners of said floor and wall panels. It is cut and folded in a manner to act in similar fashion as a Simpson post or beam connector, stabilizing the connection point. Rim member stud 73 is shown and acts to interlock said C channel frames 74 in place as well as create a cavity for the opportunity of installing service lines for electricity or plumbing.

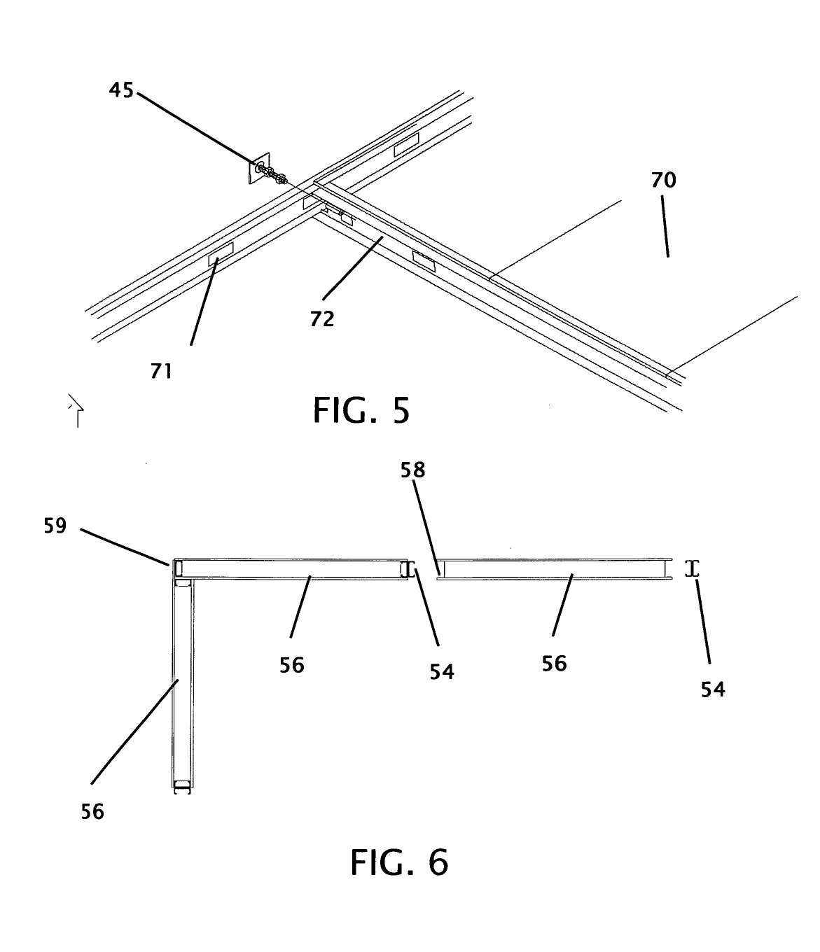

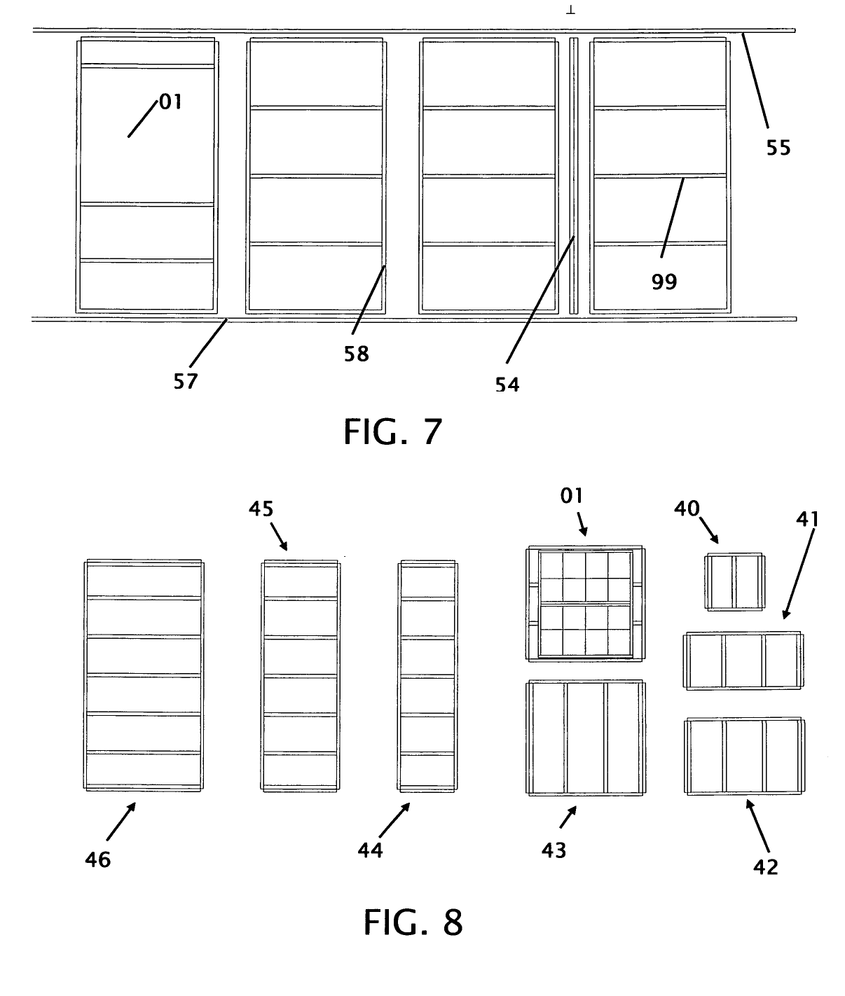

FIG. 4 shows an offset type joint for floor panels occurring at intersections within the floor area. Cross H beam member 72 generally 4′ or 8′ in length is bolted to H beam lengths 71 with thru bolt as seen in FIG. 5. C channel 74 serves the multi-purpose of providing a location to attach lumber sub purlins as shown in FIGS. 7 and 8. As well as offering edge support for interior drywall or paneling, plywood or any other material suitable for wall and floor assemblies.

FIG. 5 shows a thru bolt 45 connection from said H beam length 71 to said cross beam 72 for offset interior joints. Semitransparent panels 70 are shown for further clarity. Hollow channel are created to protect service lines from weather and rodents where installation is desired.

FIG. 6 shows a top view of typical H post 54 and intended locking location with C channel 58 of wall assembly 56. Corner detail 59 shows a shortened wall panel 56 to accommodate desired layout.

FIG. 7 shows individual wall frames with C channel wrap 58. Panels will lock together around wall post 54 and drop down onto bottom plate 57. Top plate 55 will then be inserted and secured with bolt to top of 54. Panel sub purlins 99 would be of preferred wood construction to match the width of the 58. Frames would be assembled on a jig in a factory environment. Insulation would be inserted and interior and exterior skins would then be applied.

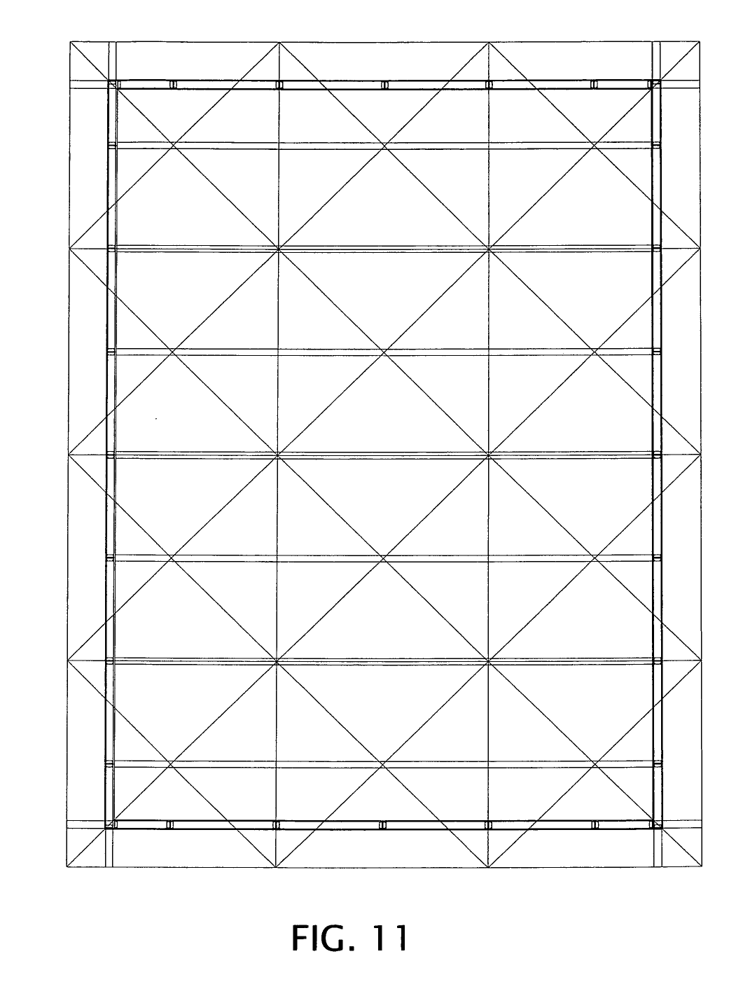

FIG. 8 shows some variety in sizes to accommodate doors and windows and the amount of desired overhang as shown in FIG. 11. In addition foam core insulated stress skin panels could be used. C channel wrap 58 would accommodate this equally well and keep the weight of the panel to a minimum. C channel overcomes separation issues known to be a deterrent when considering the use of stress skin foam core insulated panels. Making the C channel an inexpensive choice to accept ready-made steel studs post member.

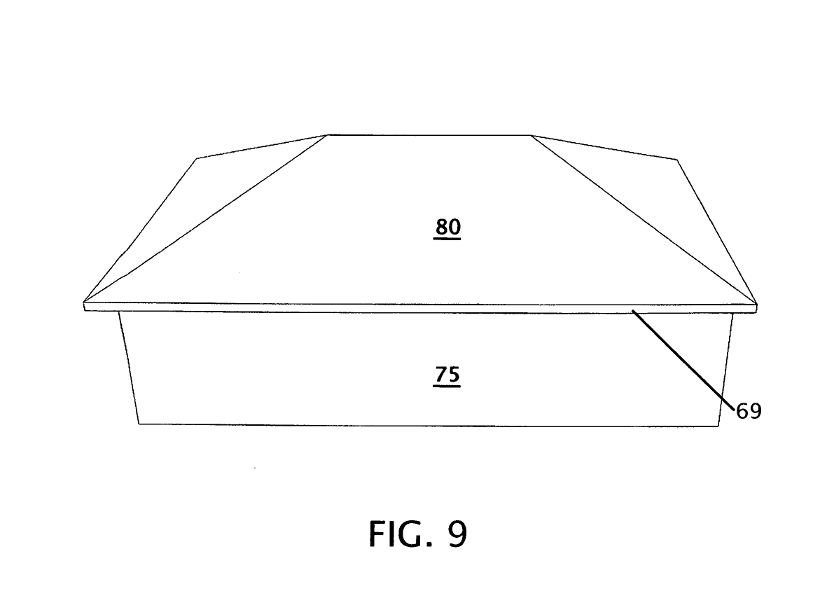

FIG. 9 shows one system objective to create a rectangular building. Roof 80 is a standard hip with a projected eve and end cap 69. A continuous wall 75 is shown as well.

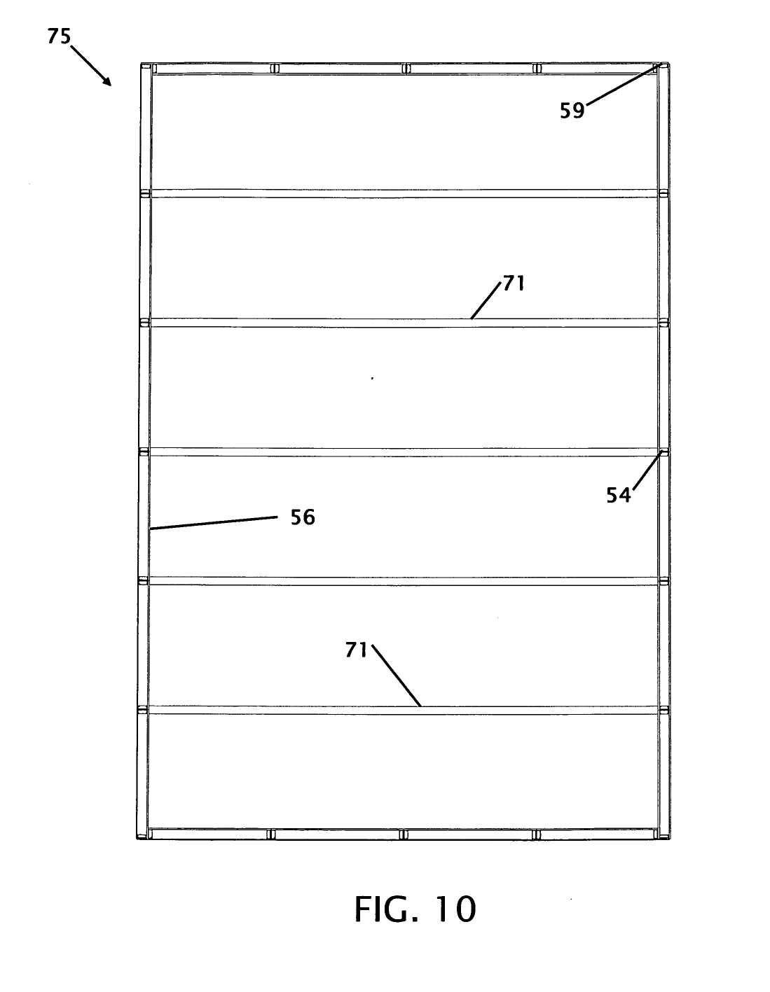

FIG. 10 shows a top view for a rectangular building with floor beam locations 71 and continuous exterior wall 75. Corner detail 59 is shown along with connection at wall post 54. Wall panels 56 are shown as well.

FIG. 11 shows a top view for a rectangular building with a wire frame diagram of the first course of the ceiling framing plan. Walls are shown below as in FIG. 10, here having an extended top plate to accommodate the corners of the overhang eve. The roof plan shows a total of 12 inter connected structural modules of the first course. This size and configuration will require another upward course to complete the exterior frame of a hip roof.

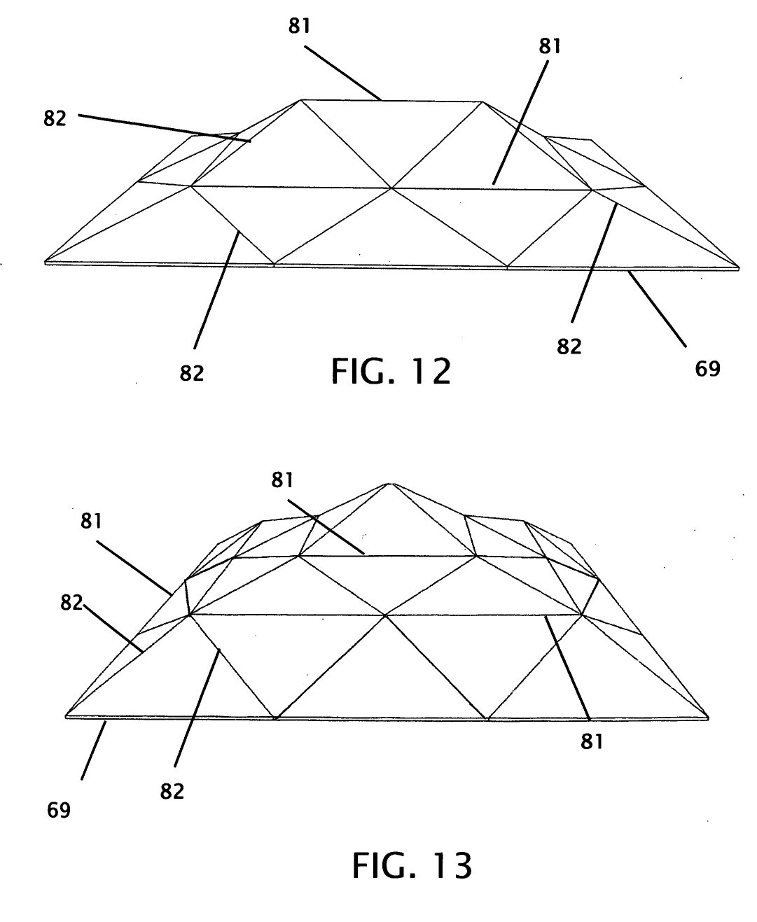

FIG. 12 shows a non-standard hip type roof. Here is the representation of a double angle hip roof. The location of horizontal 81 and diagonal framing members 82 are shown In addition 69 of the ceiling frame is shown at its connection point to the exterior of the roof frame. Joint locations are also shown. The frame is essentially ready to insert prefabricated ceiling panels or the application of a standard construction method.

FIG. 13 shows a non-standard pyramid type roof. Here is the representation of a triple tiered roof. The location of horizontal 81 and diagonal framing members 82 are shown In addition 69 of the ceiling frame is shown at its connection point to the exterior of the roof frame. Joint locations are also shown. The frame is essentially ready to insert prefabricated ceiling panels or the application of a standard construction method for a triple angle pyramid roof.

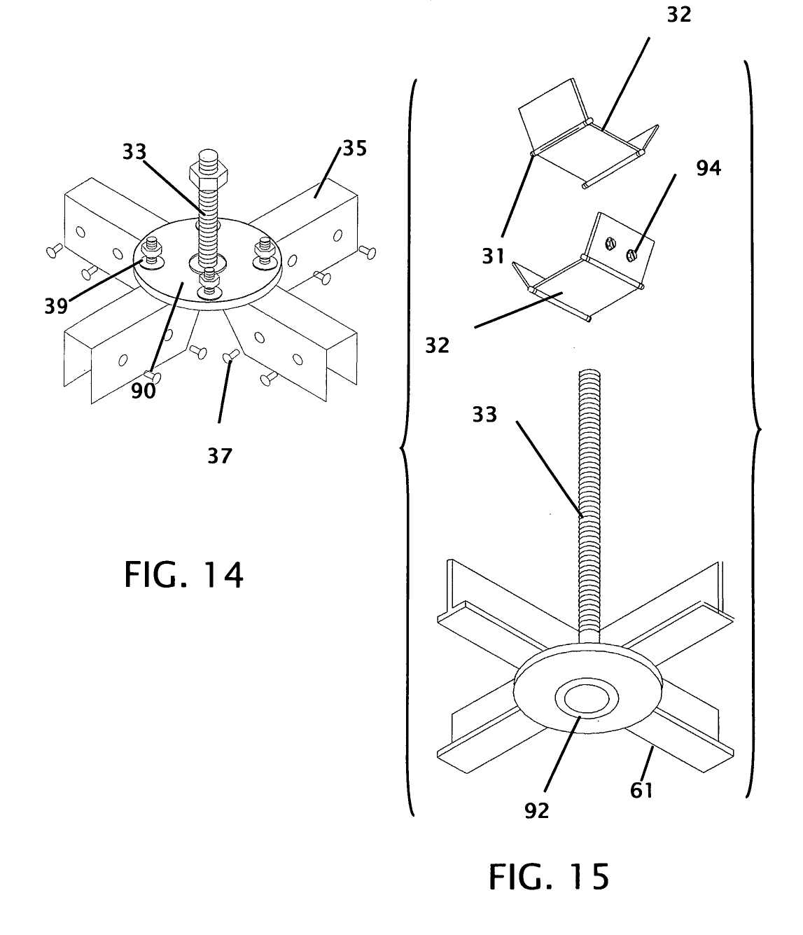

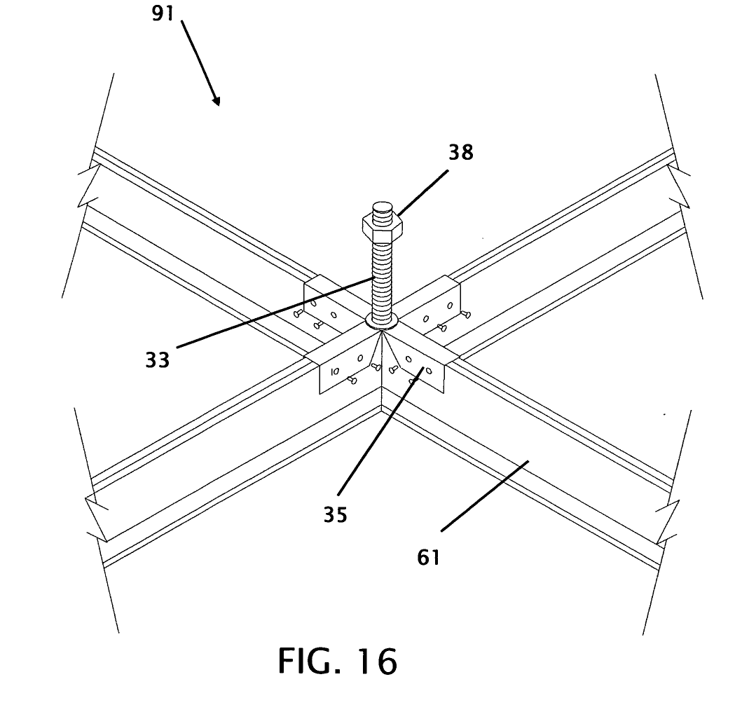

FIG. 14 shows a top piece 35 metal connector for a central T bar ceiling joint 62. Connector includes ring attachment 90 with bolt locations 39 for angled couplers or struts. Coupler is used at junction 62 to attach ceiling T bars 61. Bolt 33 is shown if FIG. 17 with detail to connect to upper union #100 in FIG. 19.

FIG. 15 shows bottom piece at junction 62 with alternate method for connecting diagonal members to bottom carriage. T bar members 61 rest on thru bolt 92 and top piece 35 is then installed to lock assembly. Adjustable hinges 32 and bolt assembly 31 give versatility in design and construction method by allowing multiple angles in roof truss frame and easy assembly with hinge pin 31.

FIG. 16 shows perspective top view of FIG. 15 ready for the installation process that follows in FIG. 17.

FIG. 17 shows upward assembly as in FIG. 16 with installation of fixed coupler 11 and connection to upper strut 34. The strut is important in that it attaches to coupler above #100 and strengthens the roof truss assembly for larger spans reducing the size and weight of tube pipe. It is important to mention that tube pipe members as in 81 and 82 could be made from a variety of materials. with couplers location and vertical member assembly.

FIG. 18 shows tube pipe connection members 10 is a 2 piece straight member with a hole for bolt 33 as mentioned. Tube pipe 10 as shown has 2 ends to receive struts but depending on location on truss frame may only need one open end or half of shown member as shown. Member 11 can be bent to most desired angles and also available with one leg only depending on location in space truss.

FIG. 19 shows a top view of a completed connector fitting with equally spaced apart couplers 10 and 11. #15 shows a 45 degree angle used to create equal angled pyramid shaped units. #16 shows a lesser angle used to create unequal angled pyramid shaped units.

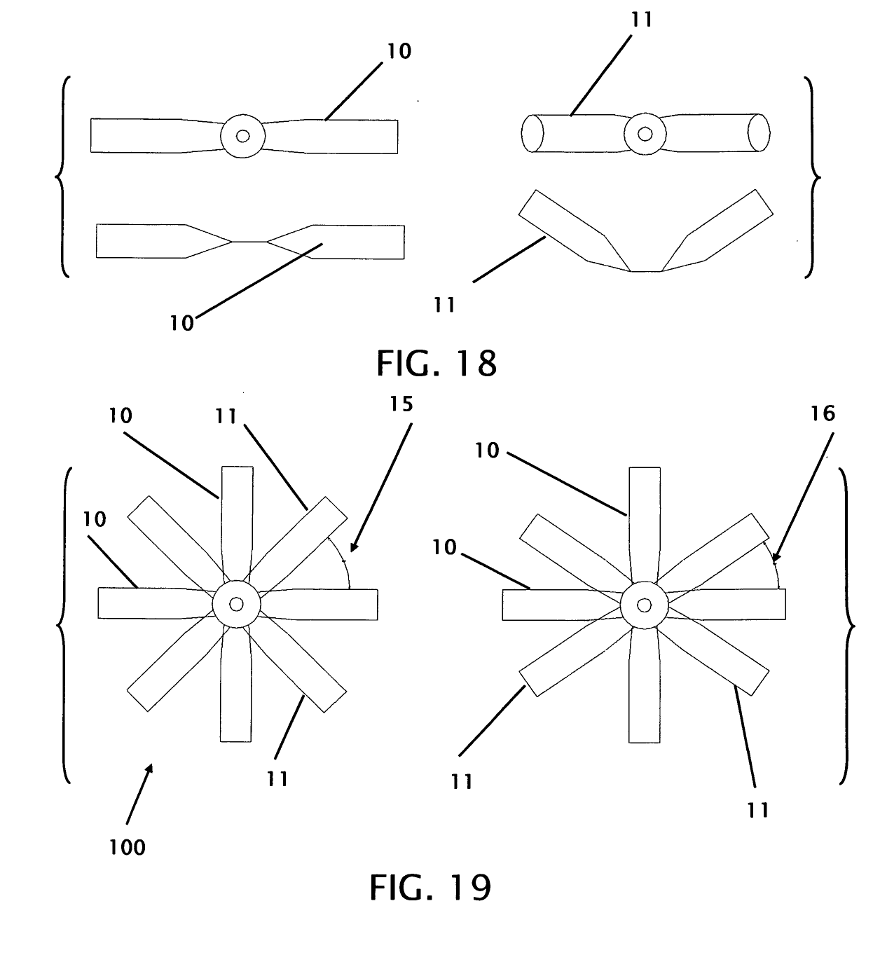

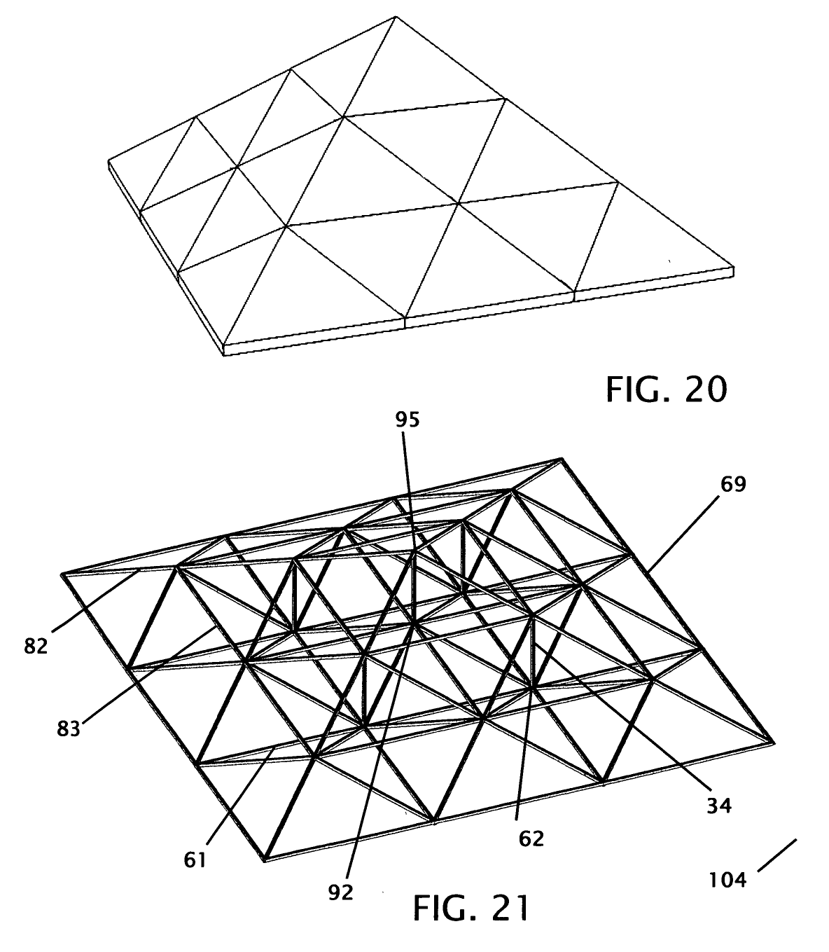

FIG. 20 shows the location of triangle shaped panels to match the location of outer frame members as shown in FIG. 21.

FIG. 21 shows an isometric view of the structural framework of a pyramid roof. The top of the space frame truss is 95. All of the rest of the numbered elements have been described in previous drawings.

FIG. 22 shows how overlapping joints for triangle fill panels and how they would lock to diagonal and horizontal members of space truss. Basically there is a left panel 22 and a right hand panel 23 overlapping the tube member 88 and sealing out moisture.

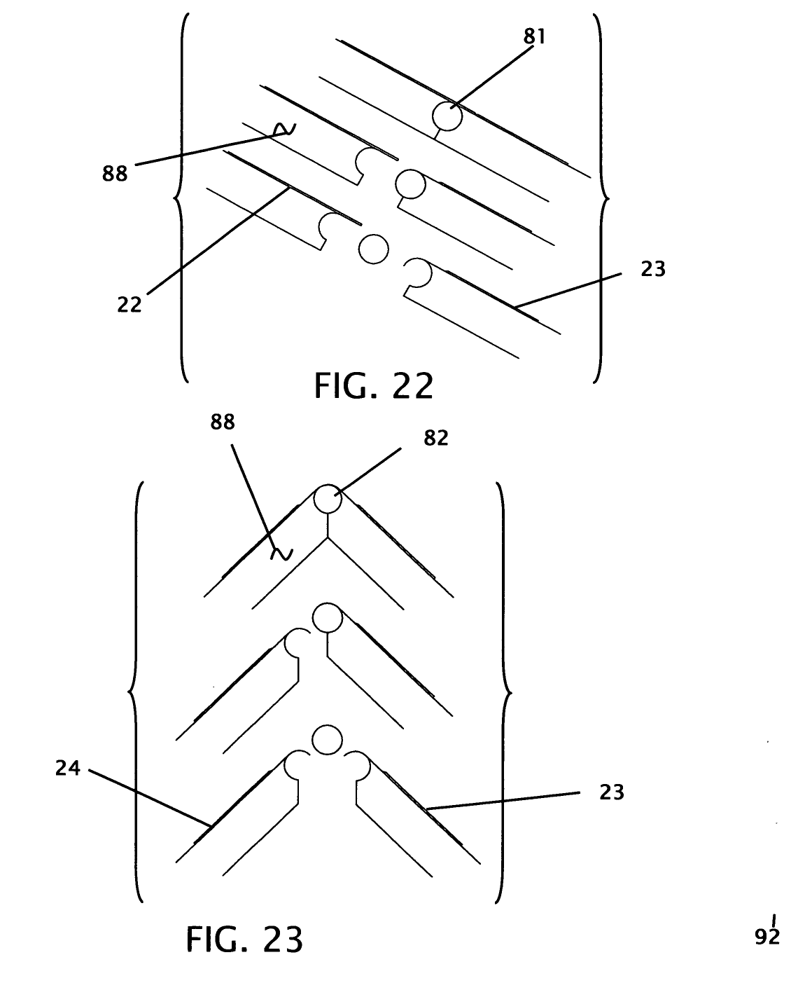

FIG. 23 shows how a corner detail would lock to diagonal members of the roof system and seal out moisture.

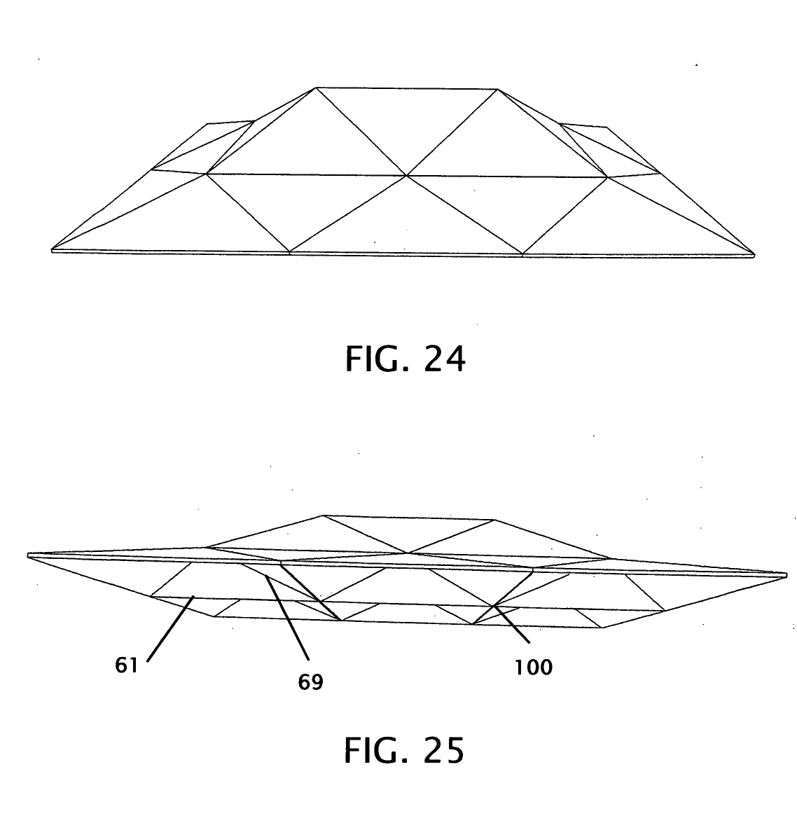

FIG. 24 shows an upper perspective view of a double angle rectangle roof, light weight for tent structures, not dissimilar as the alternate roof discussed above.

FIG. 25 shows a lower perspective view of the same roofs lower carriage structure and tubular lighter weight assembly.

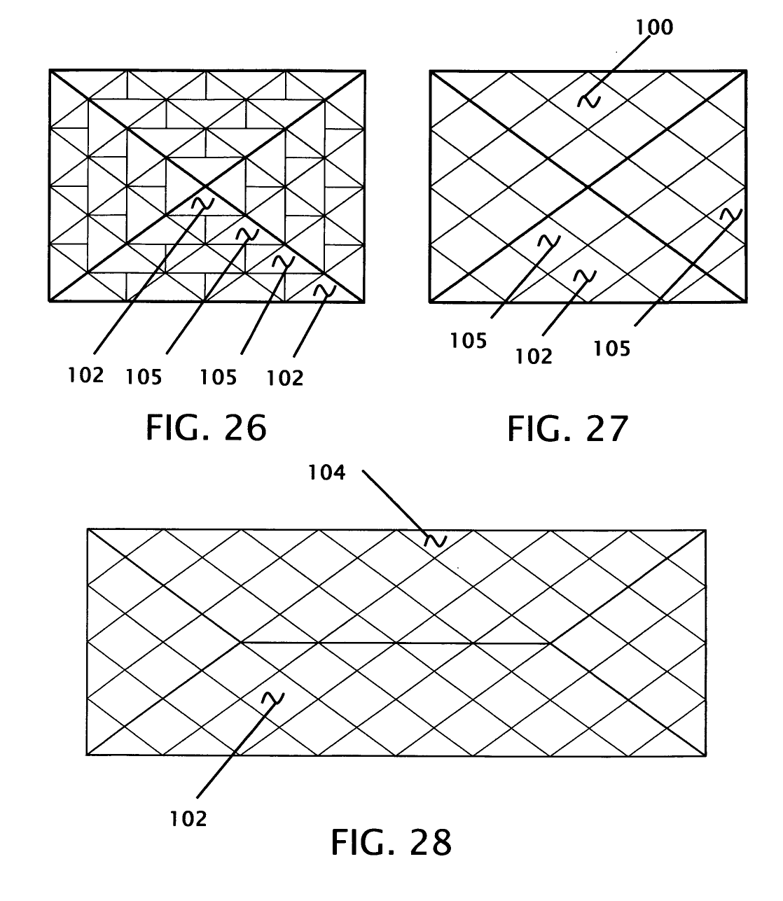

FIG. 26 shows a 4 tier or stacked rectangular roof and location of rectangular units to create a right angle hip on 2 sides for right angle solar panels

FIG. 27 shows the panel locations using quadrilateral panels and can be divided in half for triangular panels.

FIG. 28 shows an elongated hip roof capable of many more solar panels.

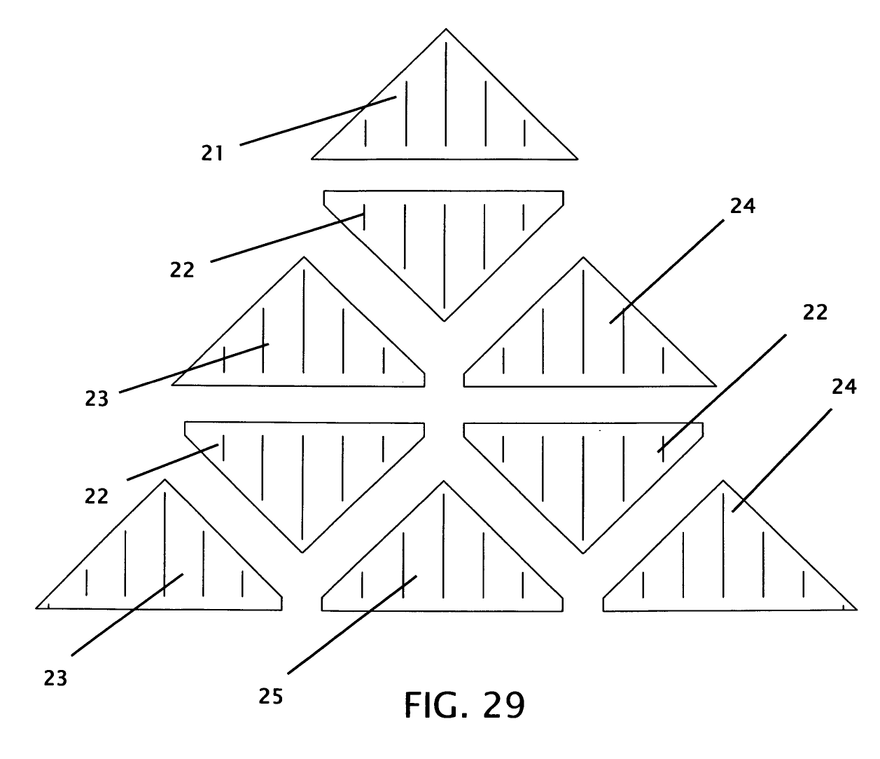

FIG. 29 shows individual triangle panels spaced apart to make a pyramid roof

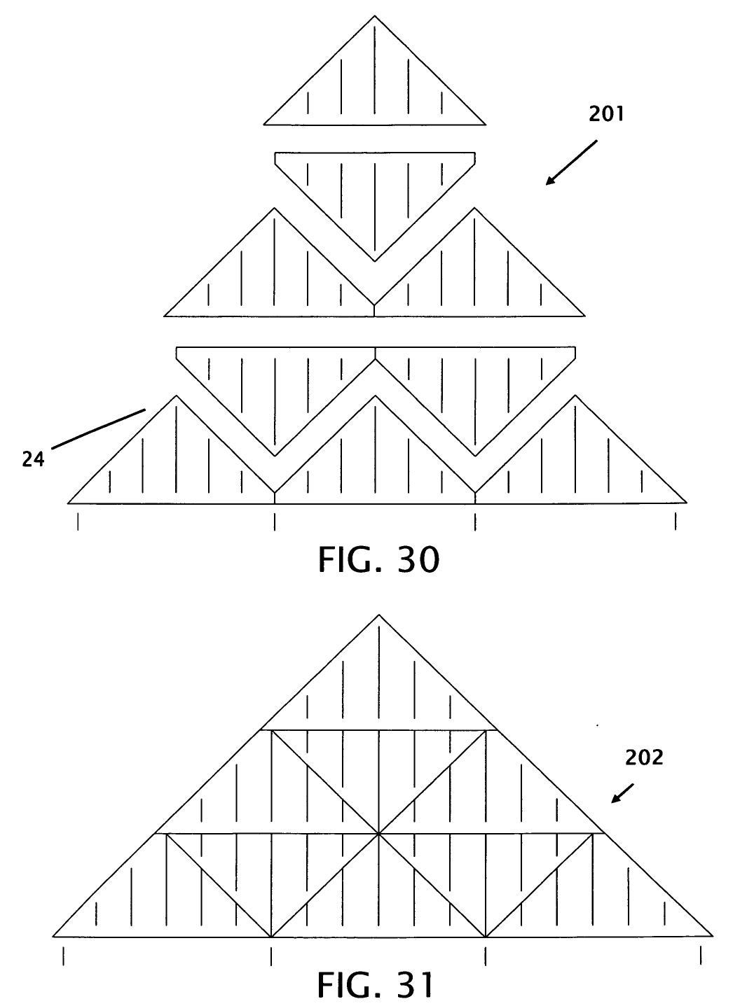

FIG. 30 shows triangle panels joined a crossed.

FIG. 31 shows triangle panels assembled across and downward to form a weather tight pyramid roof

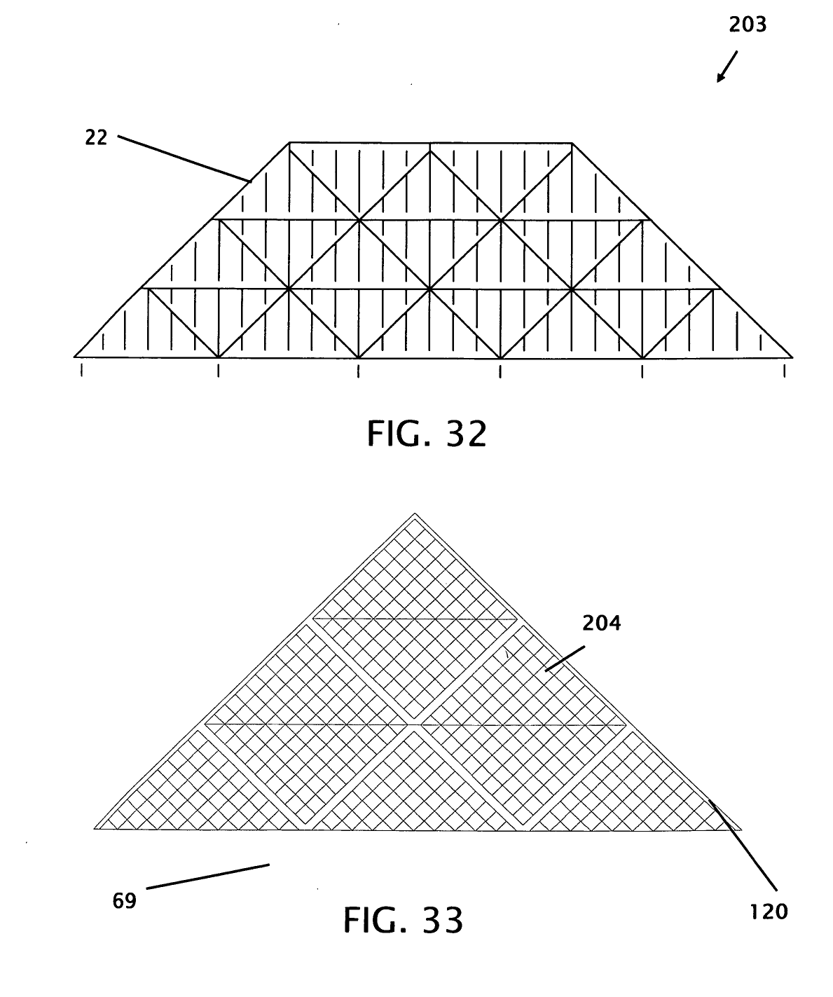

FIG. 32 shows interlocking solar panels for an elongated solar hip roof.

FIG. 33 shows a perspective view of interlocking solar panels.

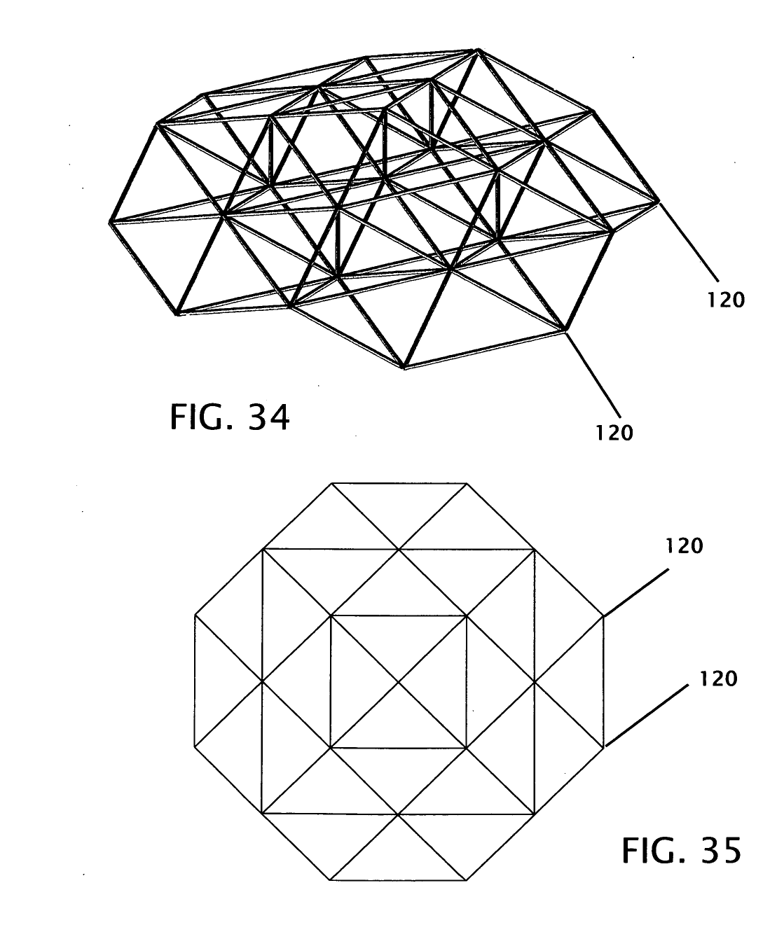

FIG. 34 shows perspective view of alternate shape and post locations.

FIG. 35 shows top view of alternate shape and post locations.

Thus, specific embodiments of a pre-fab modular dwelling with integrated solar hip roof have been disclosed. It should be apparent, however, to those skilled in the art that many more modifications besides those described are possible without departing from the inventive concepts herein. The inventive subject matter, therefore, is not to be restricted except in the spirit the appended claims.

1. Modular system with solar roof comprising:
a modular roof system constructed from a plurality of structural modules;
said structural modules having planar sides and one base side;
said planar sides having 4 equal-length diagonal members, each having an end point joined together at a common diagonal member junction;
said diagonal members being of tubular or rectangular shaped cross section;
said base side having 4 horizontal members, each having an end point in common with at least one other base member and at least one said diagonal member joined together at a common junction;
said base members being of tubular or L shape.

2. The modular system with solar roof of claim 1 where two or more structural modules are combined in outward planar directions, having at least one top horizontal connecting member attached at said diagonal member junctions.

3. The modular system with solar roof of claim 1 whereby 1 or more structural modules are stacked in an upward direction upon 4 or more structural modules assembled in outwardly rectangular directions.

4. The modular system with solar roof of claims 1, 2, and 3 whereby outermost said diagonal members accept at least one triangle-shaped cover piece;
said triangle-shaped cover piece has an exterior weatherproof skin;
said triangle-shaped cover piece has attachment means to outermost diagonal members;
said triangle-shaped cover piece has at least one overlapping edge.

5. The modular system with solar roof, according to claim 1, whereby said triangle-shaped cover piece is installable from within said structure.

6. The modular system with solar roof, according to claim 4, whereby said triangle-shaped cover piece is a stress skin panel having R-value.

7. The modular system with solar roof, according to claim 6, whereby said stress skin panel has interlocking means of attachment to said diagonal members.

8. The modular system with solar roof, according to claim 6, whereby thin film solar cells are attached to said stress skin panel.

9. The modular system with solar roof, according to claim 8, whereby said solar cells generates electricity.

10. The modular system with solar roof, according to claim 8, whereby a second electricity generating panel is connected to a first solar cell panel by through means to underside of said stress skin panel.

11. The modular system with solar roof, according to claim 6, whereby solar power cells are connected to an energy distribution source.

12. The modular system with solar roof, according to claim 11, whereby said energy distribution source uses hollow top plate of said wall system claim 21 to route wiring.

13. The modular system with solar roof of claim 1 whereby connections at intersecting joints are done with couplers.

14. The modular system with solar roof, according to claim 1, further includes a hanging connection.

15. The modular system with solar roof, according to claim 1, whereby the hanging connection supports a stress skin panel ceiling.

16. The modular system with solar roof, according to claim 15, whereby drop ceiling is a stress skin panel with an R-value core.

17. The modular system with solar roof, according to claim 6 and claim 16, whereby R-value panels create an insulated foyer-type space thereby allowing temperatures to be regulated with a fan.

18. The modular system with solar roof, according to claim 1, whereby said tubular members are connected with a hinged coupler.

19. The modular system with solar roof, according to claim 18, further includes a bolt attachment for couplers or struts.

20. The modular system with solar roof, according to claim 1, whereby roof loads are transferred to footings with posts spaced apart at roof member junctions.

21. The modular system with solar roof, according to claim 20, whereby a modular wall system is used to cover openings between said spaced-apart posts.

22. The modular system with solar roof, according to claim 21, whereby said modular wall system includes an interior and exterior skin.

23. The modular system with solar roof, according to claim 21, whereby a modular floor system shares common bearing points with modular wall system.

24. The modular system with solar roof, according to claim 1, whereby said modular roof provides connection for electrical connection to said modular wall system.
